(19) United States
(12) Patent Application Publication
(10) Pub. No.: US 2026/0343793 A1
(43) Pub. Date: Oct. 29, 2026

(54) COMPUTER CASE WITH CROSS-FLOW FAN

(71) Applicant: Shanghai TRYX Technology Co., Ltd., Shanghai (CN)

(72) Inventors: CHIH-HSUAN LIN, Shanghai (CN); Chi LIU, Shanghai (CN); Xingzhe WANG, Shanghai (CN); Silong LAN, Shanghai (CN)

(21) Appl. No.: 19/435,722

(22) Filed: Dec. 29, 2025

(30) Foreign Application Priority Data
Apr. 28, 2025 (CN) 202520825274.8

(51) Int. Cl. H05K 7/20

(52) U.S. Cl. CPC H05K 7/20172; H05K 7/20145

(57) ABSTRACT

The invention provides a computer case equipped with a cross-flow fan. The computer case comprises a housing and a cross-flow fan, wherein the cross-flow fan is mounted inside an inner cavity of the housing. The housing comprising a first side panel and a second side panel opposite to the first side panel. A main control board is mounted on the inner wall of the first side panel, and a notch is provided on the second side panel. An air inlet of the cross-flow fan is mounted corresponding to the notch, allowing the cross-flow fan to draw air from the notch. An air outlet direction of the cross-flow fan is perpendicular to an air inlet direction of the cross-flow fan, such that the air outlet direction is parallel to the main control board. By adopting a cross-flow fan with single-side air intake, the invention effectively dissipates the heat generated by the components inside the computer case. The notch provided on the side panel facilitates installation and maintenance, eliminates airflow recirculation, and improves the effective air volume.

### CROSS REFERENCE OF RELATED APPLICATIONS

The present application claims the priority of the Chinese utility model patent application which application number is 202520825274.8 filed Apr. 28, 2025, and the contents of which are hereby incorporated into this application by reference.

### FIELD OF TECHNOLOGY

The invention relates to the technical field of computer cases, particularly to a computer case equipped with a cross-flow fan.

### BACKGROUND

A computer case is an important component of a computer, mainly used to accommodate and secure various parts. In order to ensure that the core electronic circuit components inside the computer case can operate normally, a heat dissipation device is usually installed.

The existing heat dissipation devices for computer cases include cross-flow fans, axial-flow fans, and so on. For example, Chinese Invention Patent CN222337555U discloses a case structure having parallel cooling channels, which includes a case body and cross-flow fans. The front end of the case body is provided with a front panel, and an air inlet is arranged on the side wall of the front panel or the case body. A positioning area is formed between the front panel and the front wall of the case body. At least one cross-flow fan is arranged within the positioning area. The cross-flow fan includes a rotating shaft seat disposed in the partitioned positioning area and fan blades mounted on the rotating shaft seat. One of the shaft seats is provided with a driving device that drives the fan blades to rotate. The fan blades are vertically arranged along the height direction of the case body, and the blades drive the airflow from the air inlet toward the rear panel of the case body. However, the cross-flow fan disclosed in this patent has problems such as low airflow channel efficiency and poor adaptability. In addition, the use of two sets of cross-flow fans in the case results in issues such as excessive noise, short airflow paths, and inconvenient maintenance.

### SUMMARY OF THE INVENTION

In view of the deficiencies in the prior art, the invention provides a computer case with a cross-flow fan that improves air outlet efficiency and facilitates installation and maintenance.

To solve the above technical problems, the invention provides a computer case equipped with a cross-flow fan, which is mainly characterized in that the computer case comprises a housing and a cross-flow fan mounted inside an inner cavity of the housing. The housing includes a first side panel and a second side panel opposite to the first side panel. A main control board is mounted on an inner wall of the first side panel, and a notch is provided on the second side panel. An air inlet of the cross-flow fan is mounted corresponding to the notch, such that the cross-flow fan draws air from the notch. An air outlet direction of the cross-flow fan is perpendicular to the air inlet direction, making the outlet airflow parallel to the main control board.

Preferably, the cross-flow fan is vertically arranged along a height direction of the housing, and the notch is provided with a dustproof baffle.

Preferably, the dustproof baffle is a magnetic-type dustproof baffle.

Preferably, the housing is provided with a front panel, and the first side panel is connected to the second side panel through the front panel. The cross-flow fan is detachably mounted on the front panel via a fixing support bracket.

Preferably, the cross-flow fan comprises fan blades, an air duct housing, and a guide cover. The air duct housing is arranged around the fan blades, forming an air duct between the inner wall of the air duct housing and the fan blades. An air inlet is formed between the inlet end of the air duct housing and the first end of the guide cover, while an air outlet is formed between the outlet end of the air duct housing and the second end of the guide cover. The second end of the guide cover is provided with a protrusion protruding toward the fan blades.

Preferably, the protrusion is U-shaped, and the air inlet, air outlet, and the protrusion all extend along an axial direction of the cross-flow fan.

Preferably, the air duct housing is L-shaped and comprises a first housing, a second housing, and an arc-shaped housing connecting the first housing and the second housing. The air inlet end of the air duct housing is located in the first housing, and the air outlet end is located in the second housing. The cross-flow fan includes an inlet grid plate mounted at the air inlet. The inlet grid plate is parallel to the second housing and perpendicular to both the first housing and the guide cover.

Preferably, the protrusion includes a first end plate, a second end plate, and a connecting portion connecting the first and second end plates. The second end plate is connected to a main body of the guide cover. Both the first and second end plates are parallel to the second housing. The air outlet is formed between the first end plate and the second housing, and the main body of the guide cover is provided with several perforations.

Preferably, the cross-flow fan further includes a main support frame. The air duct housing is disposed on the main support frame to form an inner cavity, in which the fan blades are mounted. The guide cover is detachably installed on the main support frame. A motor accommodating shell is arranged below the inner cavity of the main support frame to house the motor, and the shell is provided with a lower cover. The top of the main support frame is provided with an upper cover.

Preferably, the motor is provided with a PWM speed control circuit module.

The computer case with a cross-flow fan of the invention adopts a single-side air intake design of the cross-flow fan, which can effectively dissipate the heat generated by components inside the case. The side panel is provided with a notch, facilitating installation and maintenance, eliminating airflow recirculation, and improving effective air volume.

### DESCRIPTION OF THE DRAWINGS

FIG. 1 is a partial exploded view of the computer case with a cross-flow fan according to the present invention.

FIG. 2 is a structural schematic view of the computer case with a cross-flow fan after assembly according to the present invention.

FIG. 3 is a structural schematic view of the computer case with a cross-flow fan when the dustproof baffle is not installed according to the present invention.

FIG. 4 is a front view of the cross-flow fan in the computer case according to the present invention.

FIG. 5 is a side view of the cross-flow fan in the computer case according to the present invention.

FIG. 6 is an exploded view of the cross-flow fan in the computer case according to the present invention.

FIG. 7 is a sectional view of the cross-flow fan in the computer case according to the present invention.

### DETAILED DESCRIPTION

To make the technical problems solved by the present invention clearer, the following detailed description is provided in conjunction with the embodiments and accompanying drawings. The specific embodiments described herein are intended only to illustrate the invention and should not be construed as limiting its scope.

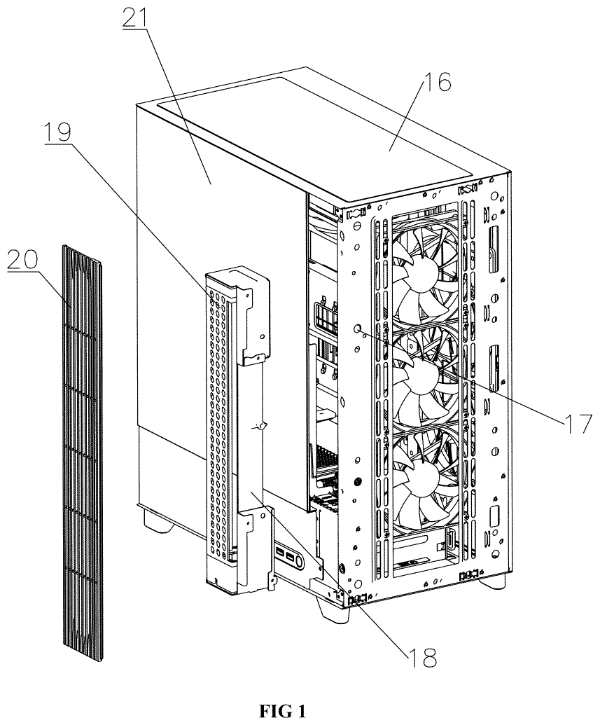

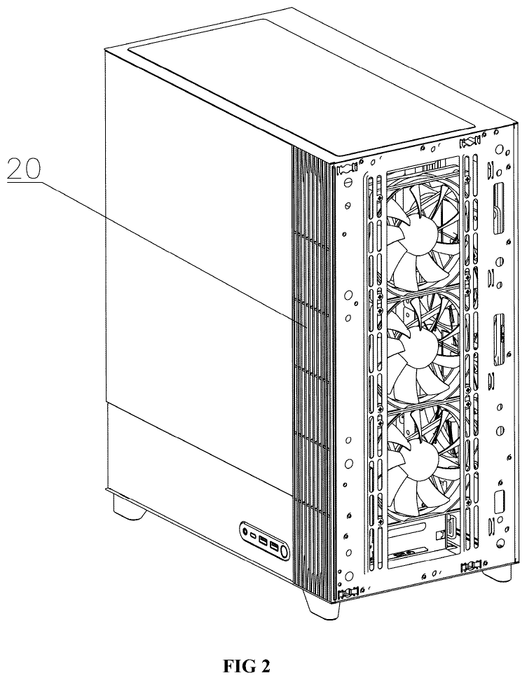

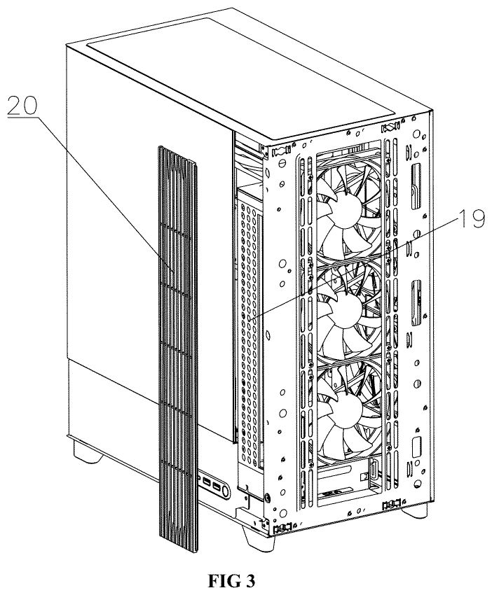

As shown in FIGS. 1 to 7, the embodiment of the computer case with a cross-flow fan according to the present invention is illustrated. The computer case comprises a housing 16 and a cross-flow fan 19. The cross-flow fan 19 is vertically mounted inside the inner cavity of the housing 16 along its height direction. The present invention does not limit the mounting orientation of the cross-flow fan 19; for example, it may also be horizontally mounted along the length direction of the housing.

The housing 16 includes a first side panel and a second side panel 21 opposite to the first side panel. A main control board is mounted on the inner wall of the first side panel, while the second side panel 21 is provided with a notch. The air inlet of the cross-flow fan 19 is mounted corresponding to the notch, enabling the cross-flow fan to draw air from the notch. The air outlet direction of the cross-flow fan 19 is perpendicular to the air inlet direction, such that the outlet airflow is parallel to the main control board. Therefore, through the specific arrangement of a single cross-flow fan, the computer case of the present invention achieves air intake vertically to the main control board on one side and air exhaust parallel to the main control board on the other side. Meanwhile, the unidirectional airflow design prevents dust intrusion (dustproof efficiency >92%). The main control board may be a PC motherboard or a separate PCB board.

As shown in FIGS. 1 to 3, the notch is a ventilation opening located on the second side panel and is provided with a detachable dustproof baffle 20. In this embodiment, the dustproof baffle 20 is a magnetic-type dustproof baffle, enabling quick assembly and disassembly (disassembly time <10 seconds). The combination of the magnetic dustproof baffle and the cross-flow fan allows directional airflow enhancement, achieving efficient heat dissipation, eliminating airflow recirculation, and improving effective air volume.

As shown in FIG. 1, the housing 16 further includes a front panel 17. The first side panel is connected to the second side panel 21 through the front panel 17. The cross-flow fan 19 is detachably mounted on the front panel 17 via a fixing support bracket 18. The cross-flow fan is installed from the side of the case through the fixing support bracket, and once secured with screws, the magnetic dustproof baffle can be attached, completing the assembly.

Based on the single-side air intake heat dissipation structure of the present invention, the noise level under full-load conditions is reduced by approximately 60% compared with conventional computer cases equipped with two cross-flow fans. Additionally, the maintenance cost is reduced, and the modular magnetic design shortens manual assembly time by 83%.

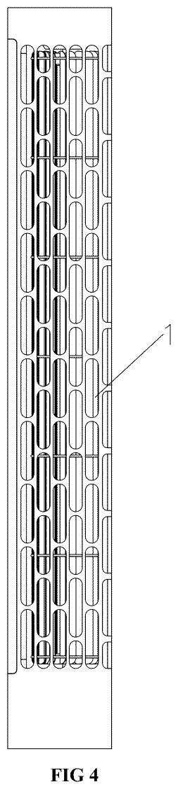

As shown in FIGS. 4 to 7, the embodiment of the cross-flow fan of the present invention relates to computer hardware cooling, particularly applicable to electromechanical devices where heat dissipation efficiency is enhanced by optimizing airflow channels and fan blade layout. The cross-flow fan comprises fan blades 3, an air duct housing 4, and a guide cover 2. The air duct housing 4 is arranged around the fan blades 3, forming an airflow duct between its inner wall and the fan blades 3.

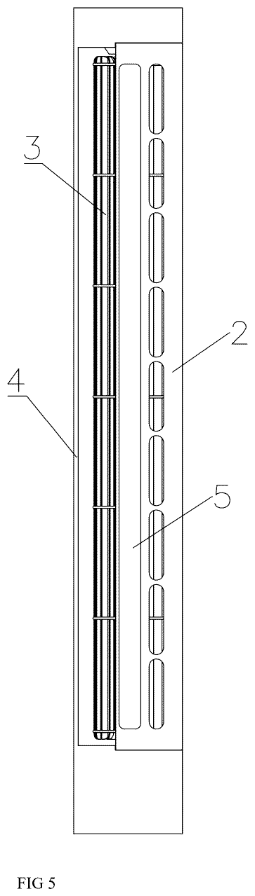

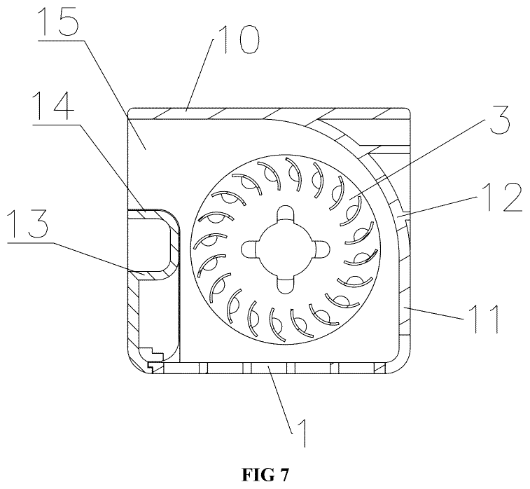

As shown in FIGS. 5 and 7, an air inlet is formed between the inlet end of the air duct housing 4 and the first end of the guide cover 2. In this embodiment, the cross-flow fan further includes an air inlet grid plate 1, which is mounted at the air inlet. Specifically, one side edge of the air inlet grid plate 1 is connected to the inlet end of the air duct housing 4, and the opposite side edge of the air inlet grid plate is connected to the first end of the guide cover 2. An air outlet 15 is formed between the outlet end of the air duct housing 4 and the second end of the guide cover 2. The second end of the guide cover 2 is provided with a protrusion 5 protruding toward the fan blades 3. As shown in FIG. 7, the protrusion 5 is U-shaped. On one hand, the design of the protrusion 5, in combination with the air duct housing and the guide cover, forms a directed airflow structure that effectively guides and intercepts airflow, increasing outlet velocity and improving airflow efficiency. On the other hand, the internal cavity of the protrusion 5 may be used to accommodate a light strip, which can be assembled or removed as needed.

As shown in FIGS. 4 to 6, the air inlet, the air outlet 15, and the protrusion 5 all extend along the axial direction of the cross-flow fan.

As shown in FIG. 7, the air duct housing 4 is L-shaped, comprising a first housing 11, a second housing 10, and an arc-shaped housing 12 connecting the first housing 11 and the second housing 10. The air inlet end of the air duct housing 4 is located in the first housing 11, and the outlet end is located in the second housing 10.

The air inlet grid plate 1 is arranged parallel to the second housing 10 and perpendicular to both the first housing 11 and the guide cover 2. The inlet grid plate functions as the air inlet, making the inlet airflow direction perpendicular to the outlet direction.

As shown in FIG. 7, the protrusion 5 includes a first end plate 14, a second end plate 13, and a connecting portion connecting the two end plates. The second end plate 13 is connected to the main body of the guide cover 2. Both end plates 14, 13 are parallel to the second housing 10, and an air outlet 15 is formed between the first end plate 14 and the second housing 10.

As shown in FIGS. 4 to 6, the main body of the guide cover 2 is provided with several axially distributed perforations.

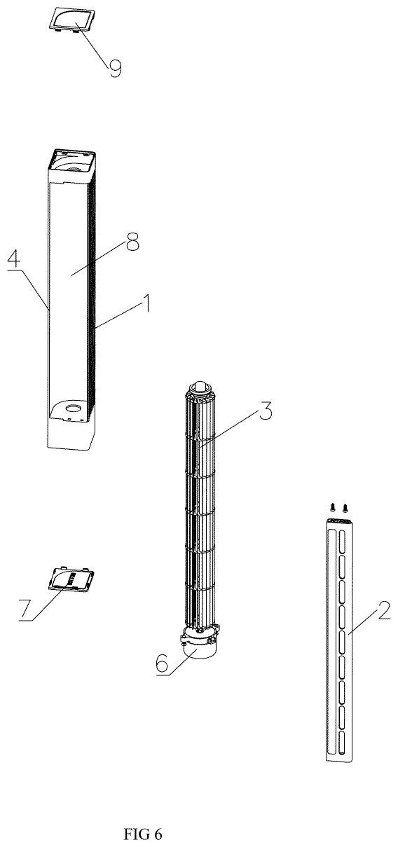

As shown in FIG. 6, the cross-flow fan further includes a main support frame 8. The air duct housing 4 and the air inlet grid plate 1 are integrally formed with the main support frame 8, forming an internal cavity in which the fan blades 3 are installed. The guide cover 2 is detachably mounted on the main support frame 8. A motor accommodating shell is provided below the cavity of the main support frame 8 to house a motor 6. The accommodating shell is provided with a lower cover 7, and the top of the main support frame 8 is provided with an upper cover 9. The fan blades 3 are fixed to the main support frame 8. The brushless motor passes through the lower end of the main support frame via a rotating shaft and is mounted inside the accommodating shell. The guide cover 2 is locked to the case bracket through buckles, and the upper and lower covers are fastened together, thereby forming the complete cross-flow fan of the present invention. The fan blades 3 may be made of aluminum alloy, while the guide cover 2 and the main support frame 8 may be made of resin plastic.

In this embodiment, the main support frame 8, the air duct housing 4, and the air inlet grid plate 1 are integrally formed. Alternatively, the air inlet grid plate may be omitted from the main support frame 8, that is, the cross-flow fan may be configured without an inlet grid plate.

The motor is equipped with a PWM speed control circuit module, which increases the rotation speed as temperature rises and decreases it as temperature falls, effectively controlling noise and enabling the airflow volume to adapt automatically to temperature changes. The motor's output connector can be connected to the electronic control mainboard of the computer case.

Through multiple experimental tests, it has been verified that when the cross-flow fan of the present invention is applied to a PC case, the cooling performance, noise control, intelligent adaptation, and reliability are all significantly improved.

The cross-flow fan of the present invention, through the cooperative design of the air inlet grid plate, air duct housing, and guide cover, effectively controls the air outlet efficiency and improves the overall heat dissipation performance when applied to a PC case.

The embodiments described above are provided merely as illustrative examples and are not intended to limit the scope of protection of the present invention. Any modifications or equivalent variations made within the technical spirit of the present invention shall fall within its scope of protection.

1. A computer case with a cross-flow fan, comprising a housing and a cross-flow fan mounted inside an inner cavity of the housing; the housing comprising a first side panel and a second side panel opposite to the first side panel; a main control board is mounted on an inner wall of the first side panel; a notch is provided on the second side panel; an air inlet of the cross-flow fan is mounted corresponding to the notch so that the cross-flow fan draws air from the notch, and an air outlet direction of the cross-flow fan is perpendicular to an air inlet direction of the cross-flow fan, such that the air outlet direction of the cross-flow fan is parallel to the main control board.

2. The computer case with a cross-flow fan according to claim 1, wherein the cross-flow fan is vertically arranged along a height direction of the housing, and a dustproof baffle is provided at the notch.

3. The computer case with a cross-flow fan according to claim 2, wherein the dustproof baffle is a magnetic-type dustproof baffle.

4. The computer case with a cross-flow fan according to claim 1, wherein the housing is provided with a front panel, the first side panel is connected to the second side panel through the front panel, and the cross-flow fan is detachably mounted on the front panel by means of a fixing support bracket.

5. The computer case with a cross-flow fan according to claim 1, wherein the cross-flow fan comprises fan blades, an air duct housing, and a guide cover, wherein the air duct housing is arranged around the fan blades, forming an air duct between the inner wall of the air duct housing and the fan blades; an air inlet is formed between an inlet end of the air duct housing and a first end of the guide cover; an air outlet is formed between an outlet end of the air duct housing and a second end of the guide cover; the second end of the guide cover is provided with a protrusion protruding toward the fan blades.

6. The computer case with a cross-flow fan according to claim 5, wherein the protrusion is U-shaped, and the air inlet, air outlet, and protrusion all extend along an axial direction of the cross-flow fan.

7. The computer case with a cross-flow fan according to claim 5, wherein the air duct housing is L-shaped and comprises a first housing, a second housing, and an arc-shaped housing connecting the first housing and the second housing; the air inlet end of the air duct housing is located in the first housing, and the air outlet end is located in the second housing; the cross-flow fan further comprises an air inlet grid plate mounted at the air inlet; the air inlet grid plate is parallel to the second housing and perpendicular to the first housing and the guide cover.

8. The computer case with a cross-flow fan according to claim 7, wherein the protrusion comprises a first end plate, a second end plate, and a connecting portion connecting the first and second end plates; the second end plate is connected to a main body of the guide cover; both the first and second end plates are parallel to the second housing; the air outlet is formed between the first end plate and the second housing; and the main body of the guide cover is provided with several perforations.

9. The computer case with a cross-flow fan according to claim 5, wherein the cross-flow fan further comprises a main support frame, the air duct housing being disposed on the main support frame to form an inner cavity, the fan blades being mounted in the inner cavity, and the guide cover being detachably mounted on the main support frame; a motor accommodating shell is arranged below the inner cavity of the main support frame to accommodate a motor, the motor accommodating shell being provided with a lower cover, and the top of the main support frame being provided with an upper cover.

10. The computer case with a cross-flow fan according to claim 9, wherein the motor is equipped with a PWM speed control circuit module.
